(19) United States
(12) Patent Application Publication
(10) Pub. No.: US 2023/0205948 A1
(43) Pub. Date: Jun. 29, 2023

(54) MACHINE LEARNING ASSISTED COMPLETION DESIGN FOR NEW WELLS

(71) Applicant: Landmark Graphics Corporation, Houston, TX (US)

(72) Inventors: Yogesh Bansal, Houston, TX (US); Gerardo Mijares, Houston, TX (US)

(21) Appl. No.: 17/560,982

(22) Filed: Dec. 23, 2021

(51) Int. Cl. G06F 30/27; G06F 30/13; E21B 47/00; E21B 49/00

(52) U.S. Cl. CPC G06F 30/27; G06F 30/13; E21B 47/00; E21B 49/00; E21B 2200/20; E21B 2200/22

(57) ABSTRACT

Systems and methods for completion design are disclosed. Wellsite data is acquired for one or more existing production wells. The wellsite data is transformed into model data sets for training a first machine learning (ML) model to predict well logs. A first well model uses the well logs to estimate production of the existing well(s). Parameters of the first well model are tuned based on a comparison between the estimated and actual production of the existing well(s). A second ML model is trained to predict parameters of a second well model for a new well, based on the tuned parameters of the first well model. The new well's production is forecasted using the second ML model. Completion costs for the new well are estimated based on the well's completion design parameters and the forecasted production. Completion design parameters are adjusted, based on the estimated completion costs and the forecasted production.

### TECHNICAL FIELD

The present description relates to well planning, completion design, and production forecasting, and particularly, to history matching techniques for tuning parameters of a wellbore model for well planning, completion design, and production forecasting.

### BACKGROUND

Oilfield operators dedicate significant resources to develop tools that help improve the overall production of oil and gas wells. Among such tools are computer-based models used to simulate the behavior of the fluids within a reservoir (e.g., water, oil and natural gas). The models can include adjustable parameters that describe three-dimensional spatial characteristics of the reservoir, one or more fractures therein, and/or dynamic features of a well system such as fluid flow and pressure characteristics at various locations within the reservoir and/or well system components. Such a model of a wellbore may, for example, enable an oilfield operator to predict future production of the wellbore as fluids are extracted from the underlying reservoir.

A history matching process may be used to ensure the accuracy of the model by matching the model's predictions of wellbore production with historical measurements of actual production obtained from the wellbore. However, conventional history matching techniques commonly require weeks to obtain history-matched model parameters and are often unable to incorporate data for the entire available production history. Accurately matching historical data can also be a challenging task given the number of modeling parameters, the complexity of their interactions, the uncertainty in the values of the parameters, and the non-uniqueness of model realizations that may match a given set of historical data.

Moreover, the knowledge and benefits derived from using conventional history matching techniques for an existing wellbore are typically lost when moving to a new wellbore. As a computer model that is tuned for an existing wellbore is generally not applicable for a new wellbore, the entire history matching process must be repeated for a new wellbore model.

### BRIEF DESCRIPTION OF THE DRAWINGS

The present disclosure is best understood from the following detailed description when read with the accompanying figures.

FIG. 1A is a perspective view of a portion of a hydrocarbon producing field including a plurality of well sites.

FIG. 1B is a diagram of an illustrative production well located in the hydrocarbon producing field of FIG. 1A.

FIG. 2 is a diagram of an illustrative drilling system with a wireline logging tool for performing wireline logging operations at a well site.

FIG. 3 is a block diagram of an illustrative system for machine learning (ML) assisted parameter matching and production forecasting.

FIG. 4 is a flow diagram of an illustrative process for parameter matching and production forecasting using ML and wellbore models.

FIG. 5 is a flow diagram of an illustrative process for transforming wellsite data into a suitable form for predictive modeling.

FIG. 6 is a diagram of an illustrative ML model in the form of an artificial neural network.

FIG. 7 is a flowchart of an illustrative process for ML-assisted parameter matching and production forecasting.

FIG. 8 is a flowchart of an illustrative process for well planning and completion design.

FIG. 9 is a block diagram of an illustrative computer system in which embodiments of the present disclosure may be implemented.

### DETAILED DESCRIPTION

Embodiments of the present disclosure relate to machine learning (ML) assisted history matching of modeling parameters for improved well planning, completion design, and production forecasting. While the present disclosure is described herein with reference to illustrative embodiments for particular applications, it should be understood that embodiments are not limited thereto. Other embodiments are possible, and modifications can be made to the embodiments within the spirit and scope of the teachings herein and additional fields in which the embodiments would be of significant utility.

It would also be apparent to one of skill in the relevant art that the embodiments, as described herein, can be implemented in many different embodiments of software, hardware, firmware, and/or the entities illustrated in the figures. Any actual software code with the specialized control of hardware to implement embodiments is not limiting of the detailed description. Thus, the operational behavior of embodiments will be described with the understanding that modifications and variations of the embodiments are possible, given the level of detail presented herein.

In the detailed description herein, references to “one or more embodiments,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to implement such feature, structure, or characteristic in connection with other embodiments whether or not explicitly described.

As will be described in further detail below, embodiments of the present disclosure use machine learning to estimate history-matched modeling parameters for well planning, completion design, and production forecasting. Conventional history matching techniques are generally limited to predicting the performance of existing wellbores drilled within a hydrocarbon producing field. By contrast, the disclosed techniques utilize artificial intelligence (AI) and machine learning (ML) to model wellbore characteristics and production history based on data acquired from one or more existing well sites to generate matching parameters for a model of a wellbore to be drilled at a new well site. In one or more embodiments, an ML model, e.g., a deep neural network, may be used to correlate the geological characteristics of one or more existing well sites to those of a new well site. The ML model may analyze the correlated characteristics along with historical production data collected for the existing well sites to determine history-matched modeling parameters that are tuned for the new well site even before drilling operations have commenced. A tuned wellbore model generated using the history-matched parameters produced by the ML model may enable more accurate production forecasts to be made for a new wellbore before it is drilled. Such guidance on future well performance would also enable oilfield operators to make more informed decisions at earlier stages of the well planning process. Accordingly, the disclosed ML-assisted history matching techniques may be used to aid oilfield operators in planning drilling operations and developing the field with greater efficiency.

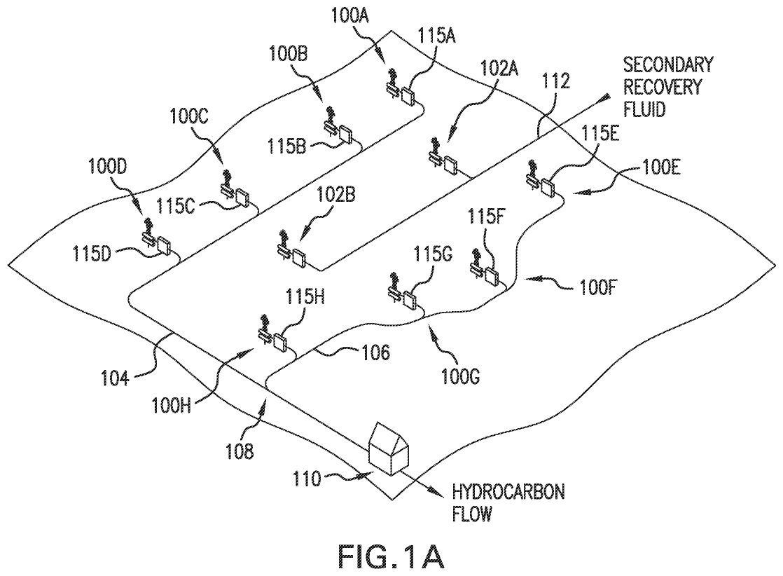

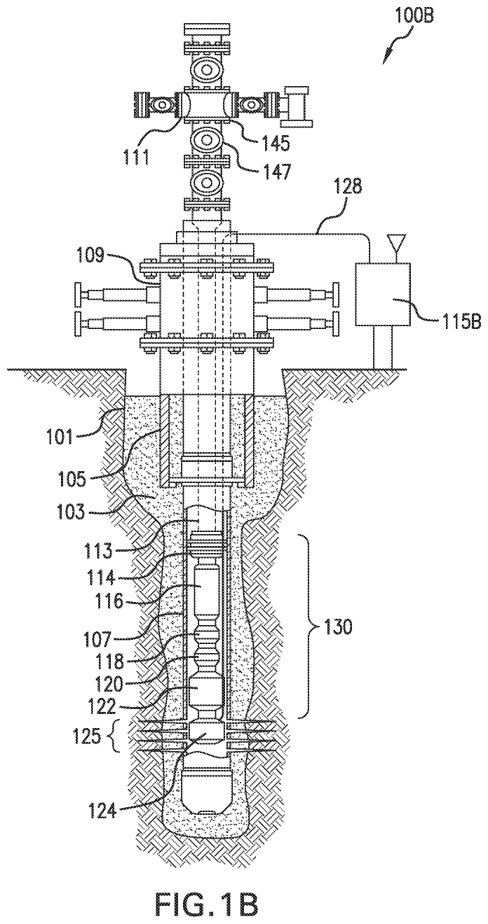

Other features and advantages of the disclosed embodiments will be or will become apparent to one of ordinary skill in the art upon examination of the following figures and detailed description. It is intended that all such additional features and advantages be included within the scope of the disclosed embodiments. While illustrative embodiments and related methodologies of the present disclosure are described below in reference to FIGS. 1A-9, it should be appreciated that the illustrated figures are only exemplary and are not intended to assert or imply any limitation with regard to the environment, architecture, design, or process in which different embodiments may be implemented.

FIG. 1A is a perspective view of a portion of a hydrocarbon producing field in accordance with embodiments of the present disclosure. As shown in FIG. 1A, the hydrocarbon producing field includes, for example, a plurality of hydrocarbon production wells 100A to 100H (“production wells 100A-H”) drilled at various locations throughout the field for recovering hydrocarbons from a subsurface reservoir formation. The field also includes injection wells 102A and 102B (“injection wells 102A-B”) for stimulating hydrocarbon production through injection of secondary recovery fluids, such as water or compressed gas, e.g., carbon dioxide, into the subsurface formation. The location of each well in this example may have been selected by a wellsite operator, e.g., according to a predetermined wellsite plan to increase the extraction of hydrocarbons from the subsurface reservoir formation. It should be noted that the number of wells shown in the hydrocarbon producing field of FIG. 1A is merely illustrative and that the disclosed embodiments are not intended to be limited thereto.

In order to gather the produced hydrocarbons for sale, the hydrocarbon field has one more production flow lines (or “production lines”). In the example of FIG. 1A, a production line 104 gathers hydrocarbons from production wells 100A-100D, and a production line 106 gathers hydrocarbons from production wells 100E-100H. The production lines 104 and 106 tie together at a gathering point 108, and then flow to a metering facility 110.

In some cases, the secondary recovery fluid is delivered to injection wells 102A and 102B by way of trucks, and thus the secondary recovery fluid may only be pumped into the formation on a periodic basis (e.g., daily, weekly). In other cases, and as illustrated in FIG. 1A, the second recovery fluid is provided under pressure to injection wells 102A and 102B by way of pipes 112.

As shown in the example of FIG. 1A, production wells 100A-H may be associated with corresponding wellsite data processing devices 115A-H located at the surface of each wellsite. As will be described in further detail below, each of data processing devices 115A-H may be used to process and store data collected by various downhole and surface measurement devices for measuring the flow of hydrocarbons at a corresponding wellsite. Each of data processing devices 115A-H may be implemented using any type of computing device having at least one processor and a memory. Data processing devices 115A-H may process and decode the digital signals received from measurement devices associated with production wells 100A-H, respectively. The measurement devices may be of any of various types and need not be the same for all of production wells 100A-H. In some cases, the measurement device associated with a production well may be related to the type of artificial lift (e.g., electric submersible, gas lift, pump jack) employed. In other cases, the measurement device for each of production wells 100A-H may be selected based on a quality of the well's hydrocarbon production, e.g., a tendency to produce hydrocarbons with excess water content.

In some implementations, one or more of the measurement devices may be in the form of a multi-phase flow meter capable of measuring hydrocarbon flow from a volume standpoint while also providing an indication of the mixture of oil and gas in the flow. Other measurement devices that may be used include, but are not limited to, oil flow meters, natural gas flow meters, and water flow meters. In some cases, the oil flow meters may be used to not only measure a rate of oil flow for a production well but also discern oil from natural gas within a hydrocarbon flow produced from the well. In some implementations, the measurement devices may also include pressure transmitters for measuring the pressure at any suitable location, such as at the wellhead, or within the borehole near the perforations.

In the case of measurement devices associated with artificial lift, the measurement devices may be voltage measurement devices, electrical current measurement devices, pressure transmitters measuring gas lift pressure, frequency meter for measuring frequency of applied voltage to electric submersible motor coupled to a pump, and the like. Moreover, multiple measurement devices may be present on any one hydrocarbon producing well. For example, a well where artificial lift is provided by an electric submersible pump may have various devices for measuring hydrocarbon flow at the surface in addition to devices for measuring performance of the submersible motor and/or pump. As another example, a well where artificial lift is provided by a gas lift system may have various devices for measuring hydrocarbon flow at the surface in addition to measurement devices for measuring performance of the gas lift system.

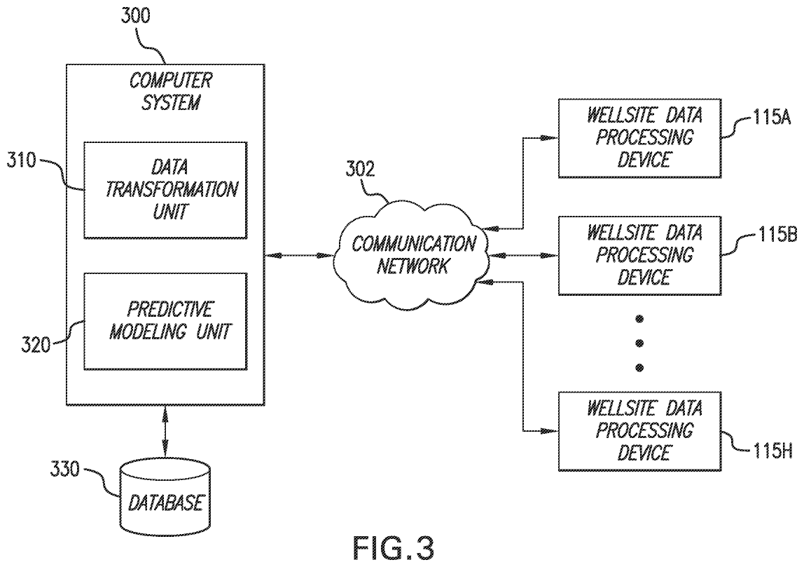

In some embodiments, the information collected by the measurement device(s) at each wellsite may be processed and stored at a data store associated with each of wellsite data processing devices 115A-H. Additionally or alternatively, the collected information may be transmitted by wellsite data processing devices 115A-H to a remote data processing system (not shown) via a communication network, such as the Internet. As will be described in further detail below with respect to FIG. 3, the remote data processing system may process the wellsite data received for one or more existing production wells to predict the performance of a new production well using the ML-assisted parameter matching techniques disclosed herein.

FIG. 1B illustrates an example of a production well 100B located in the hydrocarbon producing field of FIG. 1A. Production well 100B in this example may be suitable for conducting hydrocarbon production and exploration operations via a borehole 101 that has been drilled into the underlying reservoir formation. Borehole 101 may be drilled to any depth and in any direction within the formation. For example, borehole 101 may be a deviated wellbore drilled to ten thousand feet or more in depth and further, may be steered horizontally or other direction at a desired angle for any distance through the formation. The production well 100B also includes a casing header 105 and a casing 107, both secured into place by cement 103. A blowout preventer 109 is coupled to casing header 105 and a production wellhead 111, which together seal in the well head and enable fluids to be extracted from the well in a safe and controlled manner.

Measured data, including the production rate of production well 100B and geophysical characteristics of the corresponding well site, may be periodically sampled and collected from the production well 100B. Such wellsite data may also be combined with measurements from other wells within the field (e.g., other production wells 100A-H of FIG. 1A, as described above), enabling the overall production rate of the field and geological state of the subsurface reservoir to be monitored and assessed. Such measurements may be taken using a variety of different downhole and surface instruments including, but not limited to, a downhole temperature and pressure sensor 118 and a downhole flow meter 120. Additional devices may also be coupled in-line to a production tubing 113 including, for example, a downhole choke 116 (e.g., for varying a level of fluid flow restriction), an electric submersible pump (ESP) 122 (e.g., for drawing in fluid flowing from perforations 125 outside ESP 122 and production tubing 113), an ESP motor 124 (e.g., for driving ESP 122), and a packer 114 (e.g., for isolating the production zone below the packer from the rest of the borehole 101).

In one or more embodiments, the above-described measurement devices may be part of a bottom hole assembly (BHA) 130 connected to the lower portion or distal end of a drill string disposed within borehole 101. Although not shown in FIG. 1B, it should also be appreciated that the BHA 130 may include additional components for supporting various functions related to the drilling operations being conducted. Examples of such components include, but are not limited to, drill collars, stabilizers, reamers, hole-openers, and other downhole tools. Examples of such downhole tools include, but are not limited to, a LWD tool, a MWD tool, and any of various sensors for measuring various downhole conditions and formation properties. The measured downhole conditions may include, for example and without limitation, the movement, location, and orientation of the BHA 130 (or drill bit attached thereto) as the borehole 101 is drilled within the formation. The information collected by these downhole tools and sensors may be transmitted, e.g., via a telemetry system of the BHA 130, to a wellsite data processing device 115B at the surface. The information may be transmitted using any suitable communication channel (e.g., pressure pulses within the drilling fluid flowing in the drill string, acoustic telemetry through the pipes of the drill string, electromagnetic telemetry, optical fibers embedded in the drill string, or any combination thereof). For example, a cable 128 coupled to wellsite data processing device 115B may be used to provide signal paths (e.g., electrical or optical paths), through which control signals may be directed from the surface to the downhole devices as well as telemetry signals from the downhole devices to the surface. It should be appreciated that any of various other types of data communication techniques may be used for sending the downhole information to the surface. Such techniques may include, for example and without limitation, wireless communication techniques and wireline or any other type of wired electrical communication techniques.

Additional surface measurement devices such a surface flow meter 145 and a surface pressure sensor 147 may be used to measure, for example, a surface flow rate, a surface pressure (e.g., the tubing head pressure) and/or aspects of the well system such as the electrical power consumption of ESP motor 124. Surface flow meter 145 and surface pressure sensor 147 may also be communicatively coupled to wellsite data processing device 115B.

As described above, wellsite data processing device 115B may be implemented using any type of computing device having at least one processor and a memory. In some implementations, wellsite data processing device 115B may function as a surface control system of production well 100B for monitoring and controlling downhole operations at the corresponding well site (e.g., via a user interface provided at a terminal or control panel coupled to or integrated with device 115B).

In one or more embodiments, wellsite data processing device 115B (and other wellsite data processing devices 115A-H in the field shown in FIG. 1A) may periodically send wellsite production data via a communication network to a remote processing system for data processing and storage. Such wellsite production data may include, for example, production system measurements from various downhole devices or surface sensors/meters, as described above. In some implementations, such production data may be sent using a remote terminal unit (not shown) of wellsite data processing device 115B. In some implementations, a local or remote data storage device may be used to store the production data received from wellsite data processing device 115B. In an example, the local or remote data storage device may be used to store historical production data including a record of actual and simulated production system measurements (e.g., including surface pressure measurements and surface flow rate measurements) obtained or calculated over time, e.g., over periodic intervals or various historical time periods. While the production well 100B is described in the context of a single reservoir, it should be noted that the implementations disclosed herein are not limited thereto and that the disclosed implementations may be applied to fluid production from multiple reservoirs in a multi-reservoir production system.

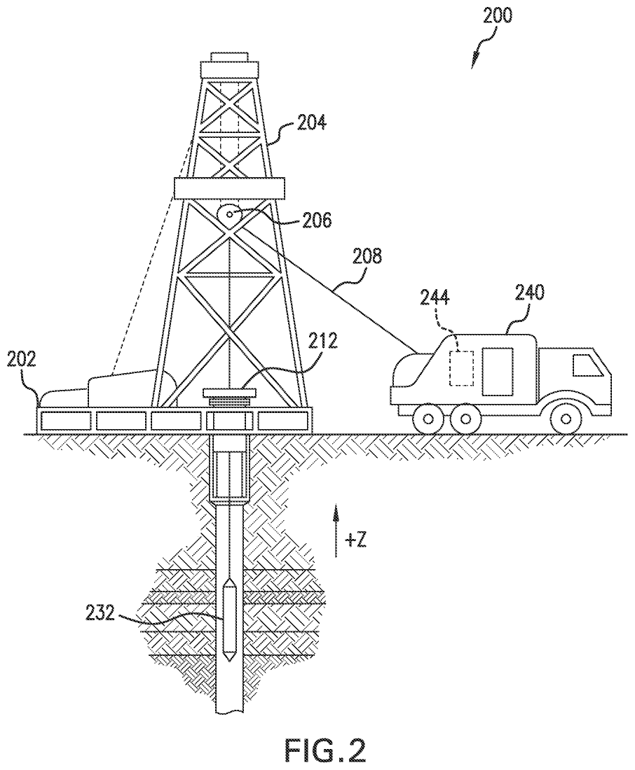

In some cases, the acquisition of geophysical measurements and/or downhole production measurements, such as measurements of downhole pressure and/or flow rates, may be disruptive to production and/or difficult or expensive to obtain continuously. Accordingly, these measurements may be obtained at or before the production stage of a well system (e.g., before, during, or after drilling) and/or only periodically (e.g., monthly) during the production stage. These measurements may be used to identify parameters of a wellbore model and to provide prior probability distributions such as ranges or weighted ranges for each parameter. In one or more embodiments, such measurements may be obtained using a wireline logging tool, as shown in FIG. 2.

FIG. 2 is a diagram of an illustrative drilling system 200 with a wireline logging tool 232 for performing wireline logging operations at a well site, e.g., the location of production well 100B within the hydrocarbon producing field of FIG. 1A. As shown in FIG. 2, drilling system 200 includes a drilling platform 202, which is equipped with a derrick 204 that supports a hoist 206. Hoist 206 is used to lower wireline logging tool 232 into the wellbore through a wellhead 212. Wireline logging tool 232 may be used to conduct logging operations downhole at various times during the drilling process. For example, a drill string (e.g., drill string attached to BHA 130 of FIG. 1B, as described above) may be removed from the wellbore periodically or after drilling has been completed, and wireline logging tool 232 may be inserted for purposes of measuring formation properties in the area surrounding the wellbore at various depths within the formation. Wireline logging tool 232 in this example may be a wireline logging sonde suspended by a cable 208 wrapped around hoist 206. Cable 208 may have conductors for transporting power to the sonde and downhole formation measurements from logging sensors of the sonde to the surface. Wireline logging tool 232 may have pads and/or centralizing springs to maintain its position near the axis of the borehole as it is pulled uphole. A logging facility 240 includes a computer 244 for processing and storing the measurements received from wireline logging tool 232.

Like wellsite data processing device 115B of FIG. 1B described above, computer 244 may be used for processing and storing downhole information, e.g., formation measurements collected by wireline logging tool 232. Also, like wellsite data processing device 115B, computer 244 may be used for monitoring and controlling downhole operations at a corresponding well site. Computer 244 may be implemented using any type of computing device having at least one processor and a memory.

In some embodiments, wellsite data processing device 115B of FIG. 1B and computer 244 of FIG. 2 may send the information collected by wireline logging tool 232 to a remote data processing system via a communication network. Such a data processing system may be implemented using any type of computing device having at least one processor, a memory, and a network interface capable of sending and receiving data to and from other computing devices via the communication network. Accordingly, it should be appreciated that, although not shown in FIGS. 1B and 2, wellsite data processing device 115B and computer 244 may be communicatively coupled to one or more remote computing devices via a network, e.g., a local area, medium area, or wide area network, such as the Internet.

As will be described in further detail below with respect to FIG. 3, the remote data processing system in the above example may be a computer system that processes the wellsite data received from computer 244 of FIG. 2 or wellsite data processing device 115B of FIG. 1B (and other wellsite data processing devices 115A-H in the field of FIG. 1A, as described above) to perform various operations related to the ML-assisted parameter matching techniques disclosed herein.

FIG. 3 is a block diagram of an illustrative system for machine learning (ML) assisted parameter matching and production forecasting. For discussion purposes, the system of FIG. 3 will be described with reference to FIG. 1A. However, it should be appreciated that the disclosed embodiments of the system are not intended to be limited thereto.

As shown in the example of FIG. 3, a computer system 300 is communicatively coupled via a communication network 302 to a plurality of wellsite data processing devices 115A-H corresponding to production wells 100A-H of FIG. 1A, as described above. In one or more embodiments, system 300 may include a data transformation unit 310 and a predictive modeling unit 320. System 300 in this example may be implemented using any type of computing device having at least one processor and a memory. The memory may be in the form of a processor-readable storage medium for storing data and instructions executable by the processor. Examples of such a computing device include, but are not limited to, a tablet computer, a laptop computer, a desktop computer, a workstation, a server, a cluster of computers in a server farm or other type of computing device.

In some implementations, system 300 may be a server system located at a data center associated with a hydrocarbon producing field, e.g., the hydrocarbon producing field of FIG. 1A, as described above. The data center may be physically located on or near the field. Alternatively, the data center may be at a remote location that is some distance, e.g., many hundreds or thousands of miles, away from the hydrocarbon producing field or region. Accordingly, system 300 may serve as a remote data processing system for processing wellsite data received from each of wellsite data processing devices 115A-H via communication network 302, as described above. Network 302 may be any type of network or combination of networks used to communicate information between different computing devices. Network 302 may include, but is not limited to, a wired (e.g., Ethernet) or a wireless (e.g., Wi-Fi or mobile telecommunications) network. In addition, network 302 can include, but is not limited to, a local area network, medium area network, and/or wide area network such as the Internet.

The wellsite data sent to system 300 by wellsite data processing devices 115A-H may include information collected for production wells 100A-H and the underlying reservoir formation associated with each wellsite. Such wellsite data may be collected using any of various downhole and/or surface measurement devices. As described above, such measurement devices may include, for example and without limitation, various sensors of a downhole tool attached to the BHA of a drill string (e.g., a LWD or MWD tool attached to BHA 130 of FIG. 1B), a downhole flow meter (e.g., downhole flow meter 120 of FIG. 1B), a surface flow meter (e.g., surface flow meter 145 of FIG. 1B), or a wireline logging tool (e.g., wireline logging tool 232 of FIG. 2), or any combination of the foregoing. The information collected by the measurement devices for each wellsite may include a combination of static data and dynamic data. The static data may include, for example, core samples, well logs, and seismic data. The dynamic data may include, for example, production data, flow rates, transient pressures, and saturations. The static and dynamic wellsite data may be generally categorized as, for example, production data, well completion data, other well-specific information, and geologic data associated with the underlying reservoir formation, as will be described in further detail below.

In one or more embodiments, system 300 may use the information received from wellsite data processing devices 115A-H for the existing production wells 100A-H to predict the future hydrocarbon production for a new production well in the field. In some embodiments, data transformation unit 310 of system 300 may process the wellsite data as it is received, e.g., as a stream of data, from wellsite data processing devices 115A-H via network 302. Additionally or alternatively, the wellsite data (or a portion thereof) received from wellsite data processing devices 115A-H may be indexed and stored in a database 330 for later access by system 300. Database 330 may be any type of data storage device, e.g., in the form of a recording medium coupled to an integrated circuit that controls access to the recording medium. The recording medium can be, for example and without limitation, a semiconductor memory, a hard disk, or similar type of memory or storage device.

In some embodiments, the wellsite data stored in database 330 may be indexed as a function of time and/or depth and then stored in association with other relevant information pertaining to the corresponding wellsite from which the data was collected and production operation conducted at that site. The indexed data may include, for example, collected measurements of well stimulation treatment parameters, such as types of materials used during different stages of stimulation, quantities of materials applied during the stimulation, rates at which materials were applied during the stimulation, pressures of application, and various cycles of stimulation treatments applied to a well. Additionally or alternatively, the indexed data may include measured drilling parameters, such as drilling fluid pressure at the surface, flow rate of drilling fluid, and rotational speed of the drill string in revolutions per minute (RPM). The indexed data may be stored in any of various data formats. In some implementations, measurement-while-drilling (MWD) or logging-while-drilling (LWD) data may be stored in an extensible markup language (XML) format, e.g., in the form of wellsite information transfer standard markup language (WITSML) documents organized or indexed by time or formation depth or both. Other types of data related to the stimulation, drilling, or production operations at each wellsite may be stored in a non-time-indexed format, such as in a format associated with a particular relational database. In other cases, historical production data for each of production wells 100A-H may be stored in a binary format from which pertinent information may be extracted for data mining and analysis purposes.

The production data stored within database 330 may include, for example, historical production data that has been aggregated over time for one or more of production wells 100A-H. The aggregated production data may be in the form of time-series data including, for example, a series of production values for one or more of production wells 100A-H at various production intervals over a given period (e.g., hourly, daily, monthly, or at evenly spaced 30-day, 60-day or 90-day production time intervals). In some embodiments, the historical production data stored for each well may also include the results of one or more well tests that were previously conducted and used to predict the well's production performance for different reservoir layers.

In addition to historical production data, database 330 may be used to store other types of information associated with production wells 100A-H and the corresponding wellsites within the hydrocarbon producing field of interest. Such wellsite data may include, but is not limited to, well-specific information, geologic data about the corresponding wellsite and underlying reservoir formation, and well completion data. Well-specific information may include, for example and without limitation, each well's name, location (e.g., longitude, latitude or X, Y coordinates), ground elevation, total depth, type (e.g., oil vs. gas), status (e.g., open vs. closed), and configuration details (e.g., vertical vs. deviated). Geologic data for each well may include, for example and without limitation, seismic data and well logs. The seismic data may include, for example, the type of seismic data, the source of the seismic data, whether the data has been migrated from one data source to another, and the format of the data (e.g., two-dimensional (2D) vs. three-dimensional (3D) data). The well log data may have been acquired using any of various well logging techniques and may include, but is not limited to, gamma ray logs, density logs, neutron porosity logs, resistivity logs, and Self Potential or Spontaneous Potential (SP) logs. Well completion data may include, for example and without limitation, drilling and completion date(s), casing size, top and bottom formation depths, pump depth, shut-in pressure, perforation information, and stimulation information. The perforation and stimulation information may include various well completion design parameters associated with each production well in this example. Examples of such completion design parameters include, but are not limited to, number of stimulation treatment stages, number of perforations (or stimulation treatment injection points) per stage, perforation dimensions (e.g., perforation size or length), treatment fluid type, and other treatment fluid parameters.

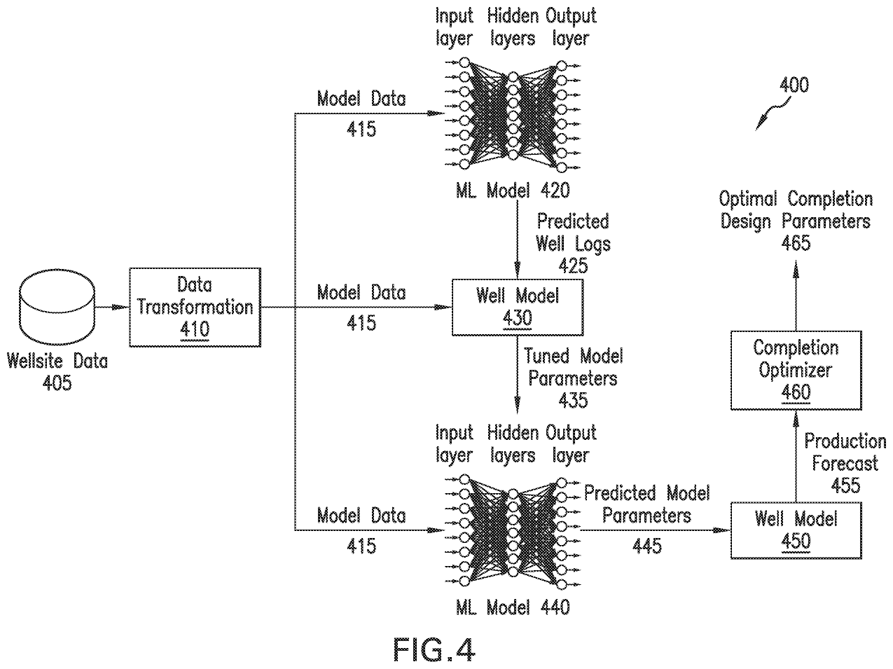

In some embodiments, historical well production and other wellsite data (e.g., well-specific information, geologic data, or well completion data or any combination thereof) may be retrieved from database 330 and provided as input to data transformation unit 310. In one or more embodiments, data transformation unit 310 may transform wellsite data into transactional model data for use by predictive modeling unit 320. As will be described in further detail below with respect to FIG. 4, the model data output by data transformation unit 310 may be provided as input to different types of predictive models used by predictive modeling unit 320 for performing the ML-assisted parameter matching and production forecasting techniques disclosed herein.

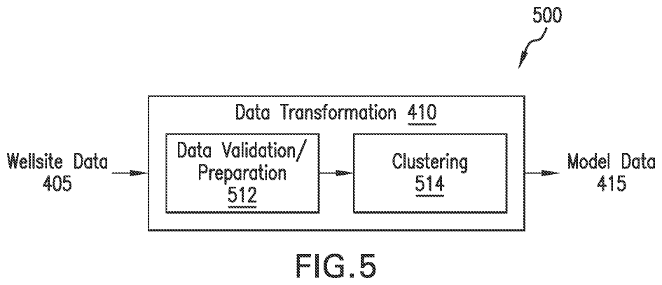

FIG. 4 is a flow diagram of an illustrative process 400 for parameter matching and production forecasting using ML and wellbore models. As shown in FIG. 4, process 400 begins with performing a data transformation 410 of wellsite data 405. The data transformation functions corresponding to block 410 of process 400 may be performed by, for example, data transformation unit 310 of system 300 of FIG. 3, as described above. In one or more embodiments, data transformation 410 may involve performing a multi-stage process to transform wellsite data 405 into model data 415 for use by predictive modeling unit 320. An example of such a data transformation process will be described in further detail below with respect to FIG. 5.

FIG. 5 is a flow diagram of an illustrative process 500 for transforming wellsite data 405 into a suitable form for predictive modeling. Wellsite data 405 may be acquired from a data store, e.g., database 330 of FIG. 3, as described above. As shown in FIG. 5, wellsite data 405 may be provided as input to a data validation stage 512 of process 500. Stage 512 may include validating and preparing raw field data into a standardized format for model building purposes. The data validation in stage 512 may include, for example, performing various quality checks to identify any data anomalies and ensure the data is complete (or sufficient for modeling purposes) as well as performing various statistical analyses to identify any outliers or inconsistencies within the data. It should be appreciated that the type of data validation that is performed may vary depending on the type of data being processed.

Once the data has been validated, process 500 may proceed to a clustering stage 514, in which the validated data may be clustered according to one or more clustering parameters. The clustering parameters may vary based on, for example, the type of clustering algorithm used to perform the clustering. In some implementations, the clustering parameters used in stage 514 may be based on various geographical or physical characteristics of production wells (e.g., production wells 100A-H of FIG. 1A, as described above) in a hydrocarbon producing field of interest. Examples of such well characteristics include, but are not limited to, the geographic location (e.g., latitude and longitude coordinates or an elevation) of each production well, a total vertical depth of each well, and a bottom hole reservoir pressure associated with each well. The clustering in stage 514 may be based on, for example, different non-linear association patterns identified within the model data 415 (or transformed wellsite data) using the clustering parameters. In one or more embodiments, the clustering parameters used to identify such patterns may include one or more geographical and physical parameters associated with each of the production wells. Such geographical and physical parameters may include any of various geological and geophysical characteristics that may influence the production of each well. Examples of such parameters include, but are not limited to, the porosity, permeability, and fluid saturation of the underlying formation associated with the geographic location of each production well.

In one or more embodiments, the clustering parameters may be determined based on user input. Referring back to FIG. 3, the clustering parameters in stage 514 may be determined based on, for example, input received from a user, e.g., a user of system 300 via a user input device (not shown) coupled to system 300. Examples of such user input device include, but are not limited to, a mouse, keyboard, microphone, touch-pad, or touch-screen display device coupled to system 300. For example, known characteristics associated with the wells or related portion of the hydrocarbon producing field or region may be presented as a list of well parameters to the user, e.g., via a display device (not shown) coupled to system 300. Such parameters may be included, for example, as part of production data or other context data associated with each well. The user may then specify the clustering parameters by selecting them directly from the displayed list, e.g., via a mouse or other user input device coupled to system 300.

Returning now to FIG. 4, model data 415 may be generated as an output of the data transformation in stage 410, e.g., including the data validation and clustering operations in stages 512 and 514, respectively, of process 500 of FIG. 5, as described above. In one or more embodiments, model data 415 may be provided as input to various predictive models to perform different functions at different stages of the predictive modeling process, e.g., as performed by predictive modeling unit 320 of FIG. 3, as described above. In one or more embodiments, model data 415 (or a relevant portion thereof) may be provided as input to an ML model 420, which may use model data 415 to map completion trends across different wells in the field and predict well logs 425 for any wells for which measured well logs are missing or determined to be incomplete. In some implementations, model data 415 may be applied to ML model 420 as training data for purposes of training ML model 420 to predict well logs and completion trends for the existing wells. The predicted well logs 425 output by ML model 420 may then be provided as input to a well model 430.

In one or more embodiments, well model 430 may be generated as a near wellbore model of one or more of the existing production wells in a hydrocarbon producing field (e.g., production wells 100A-H of FIG. 1A, as described above), based on the model data 415 and the predicted well logs 425. The near wellbore model may represent, for example, various geophysical properties associated with the wellbore and surrounding reservoir formation at various depths. The near wellbore model may also represent the fluid flow in the wellbore and its interaction with the rock formation at various interface points between the wellbore and the reservoir regions near the wellbore. Well model 430 may be used to estimate hydrocarbon production for one or more of the existing production wells in the field. The estimated production output by well model 430 may be compared to actual production data (e.g., as included within model data 415) and one or more parameters of well model 430 may be adjusted (or “tuned”) accordingly. For example, well model 430 may include various adjustable parameters, such as one or more geophysical parameters, one or more well system parameters, and/or one or more fluid parameters. Geophysical parameters may be parameters that describe characteristics of a reservoir in the oilfield (e.g., a permeability and/or a porosity of a formation layer or other component of a reservoir or a portion of a reservoir, a number of formation layers, a thickness or other spatial characteristic of a formation layer, or the like). Fluid parameters may include parameters that describe fluid flow, pressure, or composition in the reservoir and/or well system such as a water saturation value or a pressure such as a downhole pressure (e.g., bottom-hole pressure associated with a production well in the oilfield) or other pressure in the reservoir and/or well system. Well system parameters may include, for example, a number of fractures, a length (e.g., a half-length) of one or more fractures, an aperture size for one or more fractures, a conductivity at a perforation, wellbore or casing features, or the like.

Initial values for the adjustable parameters of well model 430 may be determined based on known geophysical features of the oilfield, reservoir and/or well system components and/or measurements obtained during drilling and/or downhole (e.g., wireline) measurements before or during the production stage of the wellbore. One or more of the model parameters (e.g., representing a porosity, a permeability, and a fluid saturation of an underlying reservoir formation) may then be tuned by, for example, applying appropriate weights to compensate for any differences between the estimated and actual production data and thereby, reduce the error of well model 430. It should be appreciated that any of various well-known history matching techniques may be used to tune the model parameters at this stage of process 400.

In one or more embodiments, tuned model parameters 435 resulting from the tuning of well model 430 may be applied as input to an ML model 440. In some implementations, the tuned model parameters 435 along with model data 415 (or a relevant portion thereof) may be used to train ML model 440 to predict a set of model parameters 445 for a well model 450. Well model 450 may be, for example, a near wellbore model (similar to well model 430). In one or more embodiments, well model 450 be generated for a new production well in the hydrocarbon producing field. Well model 450 may be used to determine a production forecast 455 for the new well based on predicted model parameters 445 output by ML model 440. In some implementations, ML models 420 and 440 and other predictive models (e.g., well models 430 and 450) may be updated periodically based on additional production data obtained from the production wells in the hydrocarbon producing field over time. For example, new production data from the field may be acquired in real-time, e.g., from wellsite data processing devices 115A-H via communication network 302 of FIG. 3, as described above. The data may be processed and applied to the predictive modeling process 400 as the data is acquired and processed (e.g., by data transformation unit 310 of FIG. 3, as described above) in order to produce updated predictions of future hydrocarbon production as the well production data changes over time.

In one or more embodiments, production forecast 455 produced by well model 450 for the new production well may be provided as input to a completion optimization system (or “completion optimizer”) 460. Completion optimizer 460 may execute a completion design workflow that produces optimal completion design parameters 465 based on production forecast 455 and expected completion costs for the new production well. The expected completion costs may be based on a variety of economic factors associated with the completion design. The economic factors may include or be related to the type of fracturing treatment planned for the production well. The fracturing treatment may be intended to establish or improve the flow of petroleum into a well completion for an extended period of time. The period of time may be dependent upon the expected lifespan of both the production well and the fracture treatment. While the fracture treatment may have a limited lifespan (e.g., two to five years), the costs associated with applying the treatment to the well may be relatively high (e.g., over $500,000 per treatment) and therefore, may significantly increase production costs over the life of the well. The effectiveness of a treatment to maximize hydrocarbon production from the well may be dependent upon the characteristics of the reservoir rock and the completion design of the well to which the treatment will be applied. Often there is considerable uncertainty of the reservoir rock characteristics. This uncertainty may be mitigated, however, by optimizing the completion design (or parameters 465 thereof) based on production forecast 455 produced by well model 450 using model parameters 445, as predicted by ML model 440. As described above, examples of completion design parameters include, but are not limited to, number of stimulation treatment stages, number of perforations (or stimulation treatment injection points) per stage, perforation dimensions (e.g., perforation size or length), treatment fluid type, and other treatment fluid parameters.

In one or more embodiments, the design workflow executed by completion optimizer 460 may include a design evaluation stage in which an initial completion design for the new production well is evaluated and a design optimization stage in which one or more parameters of the completion design are adjusted based on the evaluation. In one or more embodiments, the evaluation stage may utilize artificial intelligence or machine learning models, e.g., neural networks, to analyze the current completion design and associated completion costs relative to the production forecast 455 produced by well model 450. Production forecast 455 may be the forecasted production of the well over a period of time (e.g., the expected lifespan of the well). The evaluation stage may also utilize support vectors to mine wellsite data obtained from various data sources. Such wellsite data may include well logs from nearby production wells, which may be used to evaluate the reservoir characteristics for one or more sections of the wellbore to be fractured. The analysis from the data mining may then be used in the optimization stage to update appropriate completion design parameters, e.g., to maximize the forecasted production of the well while keeping completion costs within any given economic or budgetary constraints for the completion design.

In one or more embodiments, the results of the analysis and/or optimization stages of the design workflow may be presented to a user of the production management system via a display of the user's computing device (e.g., wellsite data processing device 115B of FIG. 1B, as described above). For example, graphical representations of the production forecast 455, completion design, and expected completion costs may be presented via, for example, corresponding visualization windows displayed in a graphical user interface (GUI) at the user's device. However, it should be appreciated that embodiments are not limited thereto and that additional information relating to the well completion design or production operations may also be presented as desired for a particular implementation. The GUI may allow the user in this example to evaluate the results of the completion design workflow and initiate additional workflows as well as view workflow progress and results.

In some implementations, completion optimizer 460 may be part of a larger production management system for managing hydrocarbon production operations throughout the field. Further, the design workflow executed by completion optimizer 460 may be, for example, one of various workflows performed by the production management system. The production management system in this example may include a suite of tools (including completion optimizer 460) that seamlessly interface with each other to generate a field wide production and injection forecast. The system may provide real time control of downhole production and injection control devices such as chokes, valves and other flow control devices and real time control of surface production and injection control devices.

Additionally, the system may provide a flexible workflow framework that 1) automates various workflows (including the completion design workflow described above) and their execution by the appropriate system components; 2) provides a common operating environment for consistent execution of the workflows, which is capable of substituting application tools at various steps in any workflow; and 3) allows additional steps to be introduced into and incorporated within any workflow. Accordingly, the production management system may incorporate the above-described design workflow performed by completion optimizer 460 into an automated workflow, which may include or integrate various additional workflows, for monitoring production operations for one or more existing wells in a hydrocarbon producing field to acquire production data for the well(s) over a period of time and automatically history matching the completion design parameters for a new well based on the acquired (historical) production data along with the estimated completion costs and well production forecasts or predictions for the new well, e.g., as produced by a corresponding wellbore model, such as well model 450 of FIG. 4, as described above. In some embodiments, the wellbore model may be a near wellbore model of the new well, as described above. The various tools and workflows of the production management system in this example may be implemented in computer software. The software may include, for example, routines, programs, objects, components, and data structures that perform particular tasks or implement particular data types. It should be appreciated that the disclosed production forecasting and completion design optimization techniques may be implemented using any number of computer systems, for example, as part of a distributed computing environment using multiple remote-processing devices that are linked through one or more communication networks. In such a distributed computing environment, the software applications (or associated program modules) may be located in both local and remote computer-storage media including memory storage devices.

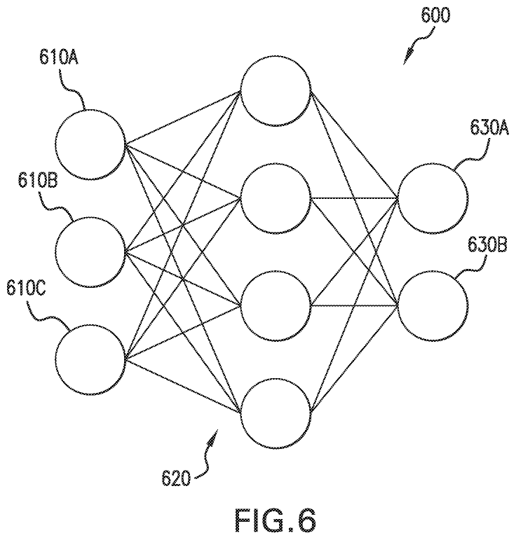

In the above example, ML models 420 and 440 may be implemented using any of various machine leaning techniques. In one or more embodiments, each of ML models 420 and 440 may be an artificial neural network (or simply, “neural network”), as shown in FIG. 6.

FIG. 6 is a diagram of an illustrative ML model 600 in the form of an artificial neural network. In the example as shown in FIG. 6, neural network 600 includes a plurality of input nodes 610a, 610b, and 610c (“input nodes 610a-c”). Input nodes 610a-c may represent points within an input layer of neural network 600 at which input parameters for different field operations are provided for processing and calculations within a hidden layer 620 of neural network 600.

Hidden layer 620 includes hidden nodes, where each hidden node may be coupled to some or all of input nodes 610a-c. The results of the processing and calculations within hidden layer 620 may include output parameters that are produced at output nodes 630a and 630b (“output nodes 630a-b”) of an output layer of neural network 600. Referring back to FIG. 4, input nodes 610a-c may represent, for example, different tuned parameters (e.g., tuned model parameters 435 corresponding to fluid porosity, permeability, and saturation) of a first near wellbore model (e.g., well model 430) representing existing production wells within a hydrocarbon producing field, as described above, and output nodes 630a-b in this example may represent corresponding predicted model parameters (e.g., predicted model parameters 445) for a second near wellbore model (e.g., well model 450) representing a new production well to be developed in the field.

In one or more embodiments, each of the hidden nodes of hidden layer 620 may perform a mathematical function or operation for estimating or predicting an optimal model parameter for the new production well based on the tuned model parameter associated with the existing wells. The mathematical function/operation may be determined or learned during a training phase of neural network 600. The mathematical operation may be performed based on the input parameter data provided at the particular input node(s) to which the hidden node is coupled. Likewise, output nodes 630a-b may perform mathematical operations based on data provided from the hidden nodes of hidden layer 620. Accordingly, each of output nodes 630a-b may represent an estimated or predicted output parameter based on the input parameter data provided at input nodes 610a-c. While three input nodes 610a-c and two output nodes 630a-b are shown in FIG. 6, it should be appreciated that neural network 600 may include any number of input and output nodes, as desired for a particular implementation. Also, while only layer 620 is shown in FIG. 6, it should be appreciated that neural network 600 may include any number of additional hidden layers, where each hidden layer may include any number of hidden nodes, as desired for a particular implementation.

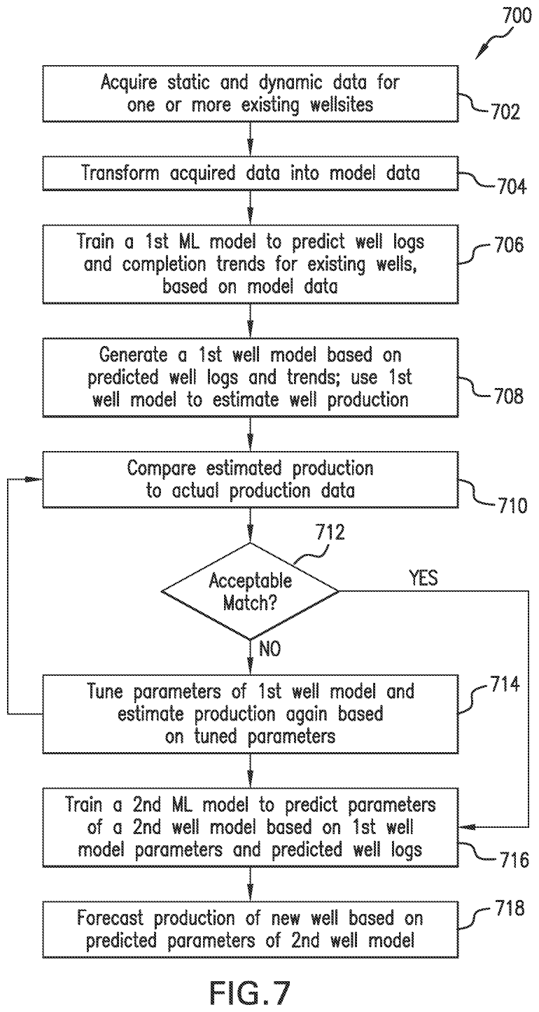

FIG. 7 is a flowchart of an illustrative process 700 for ML-assisted parameter matching and production forecasting. For discussion purposes, process 700 will be described with reference to portions of system 300 of FIG. 3 as well as processes 400 and 500 of FIGS. 4 and 5, respectively, as described above. However, it should be appreciated that process 700 is not intended to be limited thereto. For example, process 700 may be performed by system 300 of FIG. 3, as described above.

As shown in FIG. 7, process 700 begins in block 702, which includes acquiring static and dynamic data for one or more existing wellsites within a hydrocarbon producing field of interest. As described above, the static wellsite data may include, for example, core samples, well logs, and seismic data. The dynamic wellsite data may include, for example, production data, flow rates, transient pressures, and saturations. Also, the static and dynamic wellsite data acquired in block 702 may be generally categorized into various categories including, for example, production data, well completion data, other well-specific information, and geologic data associated with the underlying reservoir formation.

In block 704, the acquired wellsite data may be transformed into model data, e.g., model data 415 of FIG. 4, as described above. Block 704 may be performed by, for example, data transformation unit 310 of FIG. 3 in stage 410 of process 400 of FIG. 4 using data transformation process 500 of FIG. 5, as described above.

In block 706, the model data (or a portion thereof) may be applied as training data for training a first machine learning (ML) model to predict well logs and completion trends for production wells at the one or more existing wellsites. The first ML model in block 706 may be implemented using, for example, ML model 420 of FIG. 4, as described above.

In block 708, a first well model (e.g., well model 430 of FIG. 4, as described above) may be generated based on the predicted well logs and completion trends produced by the first ML model, as trained in block 706. The first well model may be, for example, a near wellbore model of the production well(s) at the one or more existing wellsites. The first well model generated in block 708 may be used to estimate the production of the existing well(s).

In block 710, the estimated production produced by the first well model may be compared to the actual production of the well(s).

In block 712, a determination is made based on the comparison in block 710 as to whether there is an acceptable match between the estimated well production produced by the model and the actual well production. In other words, block 710 may include determining whether any difference between the estimated well production produced by the model and the actual well production is acceptable, e.g., within an acceptable error tolerance range.

If it is determined in block 712 that there is no acceptable match between the estimated and actual production of the wells, then process 700 proceeds to block 714. In block 714, parameters of the first well model generated in block 708 are tuned and the tuned first well model (or first well model with the tuned parameter) is used to estimate production again. After block 714, process 700 returns to block 710 to repeat the operations in blocks 710 and 712 based on the production estimated using the well model with the tuned model parameters. It should be appreciated that the operations in blocks 710, 712, and 714 may be repeated for any number of interactions until it is determined block 712 that there is an acceptable match between the modeled or estimated and actual production data.

If (or when) it is determined in block 712 that there is an acceptable match between the estimated and actual production of the wells, then process 700 proceeds to block 716. In block 716, the model parameters of the first well model, as tuned by the first ML model, are used to train a second ML model to predict the parameters of a second well model for a new production well to be developed in the field. In some embodiments, the second ML model may be trained using a combination of the tuned model parameters of the first well model along with the predicted well logs from block 706 and other model data produced from the transformed wellsite data in block 704.

Process then proceeds to block 718, which includes forecasting production of the new production well based on the predicted parameters of second well model.

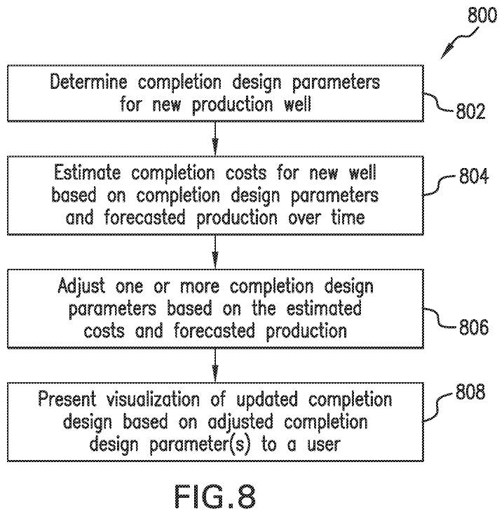

FIG. 8 is a flowchart of an illustrative process 800 for well planning and completion design. Like process 700 of FIG. 7 describes above, process 800 will be described with reference to portions of system 300 of FIG. 3 as well as processes 400 and 700 of FIGS. 4 and 7, respectively, as described above. However, it should be appreciated that process 800 is not intended to be limited thereto. Also, like process 700, process 800 may be performed by, for example, system 300 of FIG. 3, as described above.

As shown in FIG. 8, process 800 begins in block 802, which includes determining completion design parameters for a new production well. In one or more embodiments, the new production well may be represented by the second well model in block 716 of process 700 of FIG. 7, as described above. Accordingly, the parameters of the second well model may include the completion design parameters of the new production well. In other words, the completion design parameters may be determined in block 802 based on the parameters of the second well model.

Process 800 then proceeds to block 804, which includes estimating completion costs for the new production well based on the completion design parameters from block 802 and the forecasted production from block 718 of process 700, as described above. The forecasted production may be the rate of hydrocarbon production expected from the new well over a period of time. The period of time may be, for example, the expected lifespan of the well or some portion thereof. In some cases, the period of time may be specified by a user, e.g., via a user interface (or GUI) of the user's computing device, as described above.

In block 806, one or more of the completion design parameters determined for the well in block 802 may be adjusted based on the completion costs estimated in block 804 and the forecasted production from block 718. As described above, the adjustment of the completion design for the new production well may be based on a completion design workflow performed by completion optimizer 460 of FIG. 4, as described above.

In block 808, a visualization of an updated completion design based on the adjusted completion design parameter(s) may be presented to a user via a display at the user's computing device. In addition to the updated completion design, the results of the analysis and/or optimization stages of the design workflow may be presented to the user, e.g., via appropriate visualization windows within a GUI at the user's device, as described above.

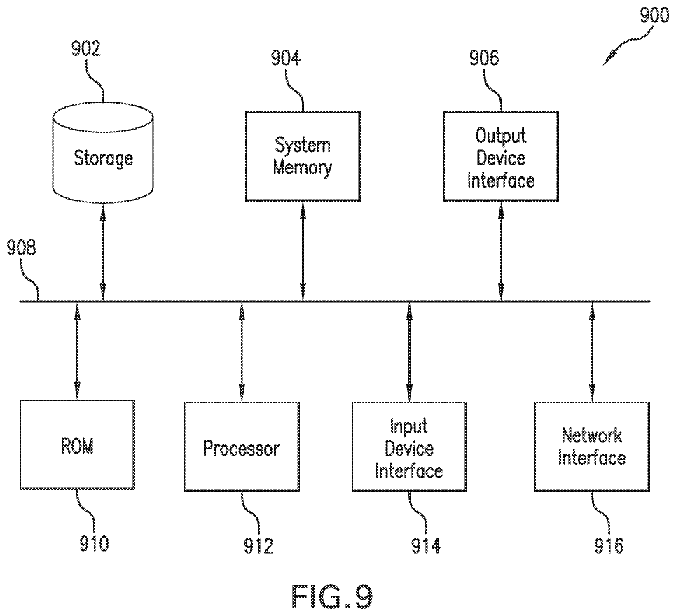

FIG. 9 is a block diagram illustrating an example of a computer system 900 in which embodiments of the present disclosure may be implemented. For example, computer system 300 of FIG. 3 along with processes 400, 500, 700, and 800 of FIGS. 4, 5, 7, and 8, respectively, as described above, may be implemented using system 900. System 900 can be a computer, phone, PDA, or any other type of electronic device. Such an electronic device includes various types of computer readable media and interfaces for various other types of computer readable media. As shown in FIG. 9, system 900 includes a permanent storage device 902, a system memory 904, an output device interface 906, a system communications bus 909, a read-only memory (ROM) 910, processing unit(s) 912, an input device interface 914, and a network interface 916.

Bus 908 collectively represents all system, peripheral, and chipset buses that communicatively connect the numerous internal devices of system 900. For instance, bus 908 communicatively connects processing unit(s) 912 with ROM 910, system memory 904, and permanent storage device 902.

From these various memory units, processing unit(s) 912 retrieves instructions to execute and data to process in order to execute the processes of the subject disclosure. The processing unit(s) can be a single processor or a multi-core processor in different implementations.

ROM 910 stores static data and instructions that are needed by processing unit(s) 912 and other modules of system 900. Permanent storage device 902, on the other hand, is a read-and-write memory device. This device is a non-volatile memory unit that stores instructions and data even when system 900 is off. Some implementations of the subject disclosure use a mass-storage device (such as a magnetic or optical disk and its corresponding disk drive) as permanent storage device 902.

Other implementations use a removable storage device (such as a floppy disk, flash drive, and its corresponding disk drive) as permanent storage device 902. Like permanent storage device 902, system memory 904 is a read-and-write memory device. However, unlike storage device 902, system memory 904 is a volatile read-and-write memory, such a random access memory. System memory 904 stores some of the instructions and data that the processor needs at runtime. In some implementations, the processes of the subject disclosure are stored in system memory 904, permanent storage device 902, and/or ROM 910. For example, the various memory units include instructions for performing the disclosed ML-assisted parameter matching and production forecasting techniques. From these various memory units, processing unit(s) 912 retrieves instructions to execute and data to process in order to execute the processes of some implementations.

Bus 908 also connects to input and output device interfaces 914 and 906. Input device interface 914 enables the user to communicate information and select commands to the system 900. Input devices used with input device interface 914 include, for example, alphanumeric, QWERTY, or T9 keyboards, microphones, and pointing devices (also called “cursor control devices”). Output device interfaces 906 enables, for example, the display of images generated by the system 900. Output devices used with output device interface 906 include, for example, printers and display devices, such as cathode ray tubes (CRT) or liquid crystal displays (LCD). Some implementations include devices such as a touchscreen that functions as both input and output devices. It should be appreciated that embodiments of the present disclosure may be implemented using a computer including any of various types of input and output devices for enabling interaction with a user. Such interaction may include feedback to or from the user in different forms of sensory feedback including, but not limited to, visual feedback, auditory feedback, or tactile feedback. Further, input from the user can be received in any form including, but not limited to, acoustic, speech, or tactile input. Additionally, interaction with the user may include transmitting and receiving different types of information, e.g., in the form of documents, to and from the user via the above-described interfaces.

Also, as shown in FIG. 9, bus 908 also couples system 900 to a public or private network (not shown) or combination of networks through a network interface 916. Such a network may include, for example, a local area network (“LAN”), such as an Intranet, or a wide area network (“WAN”), such as the Internet. Any or all components of system 900 can be used in conjunction with the subject disclosure.

These functions described above can be implemented in digital electronic circuitry, in computer software, firmware or hardware. The techniques can be implemented using one or more computer program products. Programmable processors and computers can be included in or packaged as mobile devices. The processes and logic flows can be performed by one or more programmable processors and by one or more programmable logic circuitry. General and special purpose computing devices and storage devices can be interconnected through communication networks.

Some implementations include electronic components, such as microprocessors, storage and memory that store computer program instructions in a machine-readable or computer-readable medium (alternatively referred to as computer-readable storage media, machine-readable media, or machine-readable storage media). Some examples of such computer-readable media include RAM, ROM, read-only compact discs (CD-ROM), recordable compact discs (CD-R), rewritable compact discs (CD-RW), read-only digital versatile discs (e.g., DVD-ROM, dual-layer DVD-ROM), a variety of recordable/rewritable DVDs (e.g., DVD-RAM, DVD-RW, DVD+RW, etc.), flash memory (e.g., SD cards, mini-SD cards, micro-SD cards, etc.), magnetic and/or solid state hard drives, read-only and recordable Blu-Ray® discs, ultra density optical discs, any other optical or magnetic media, and floppy disks. The computer-readable media can store a computer program that is executable by at least one processing unit and includes sets of instructions for performing various operations. Examples of computer programs or computer code include machine code, such as is produced by a compiler, and files including higher-level code that are executed by a computer, an electronic component, or a microprocessor using an interpreter.

While the above discussion primarily refers to microprocessor or multi-core processors that execute software, some implementations are performed by one or more integrated circuits, such as application specific integrated circuits (ASICs) or field programmable gate arrays (FPGAs). In some implementations, such integrated circuits execute instructions that are stored on the circuit itself. Accordingly, the operations for performing processes 400, 500, 700, and 800 of FIGS. 4, 5, 7, and 8, respectively, as described above, may be implemented using system 900 or any computer system having processing circuitry or a computer program product including instructions stored therein, which, when executed by at least one processor, causes the processor to perform functions relating to these processes.

As used in this specification and any claims of this application, the terms “computer”, “server”, “processor”, and “memory” all refer to electronic or other technological devices. These terms exclude people or groups of people. As used herein, the terms “computer readable medium” and “computer readable media” refer generally to tangible, physical, and non-transitory electronic storage mediums that store information in a form that is readable by a computer.

Embodiments of the subject matter described in this specification can be implemented in a computing system that includes a back end component, e.g., as a data server, or that includes a middleware component, e.g., an application server, or that includes a front end component, e.g., a client computer having a graphical user interface or a Web browser through which a user can interact with an implementation of the subject matter described in this specification, or any combination of one or more such back end, middleware, or front end components. The components of the system can be interconnected by any form or medium of digital data communication, e.g., a communication network. Examples of communication networks include a local area network (“LAN”) and a wide area network (“WAN”), an inter-network (e.g., the Internet), and peer-to-peer networks (e.g., ad hoc peer-to-peer networks).

The computing system can include clients and servers. A client and server are generally remote from each other and typically interact through a communication network. The relationship of client and server arises by virtue of computer programs running on the respective computers and having a client-server relationship to each other. In some embodiments, a server transmits data (e.g., a web page) to a client device (e.g., for purposes of displaying data to and receiving user input from a user interacting with the client device). Data generated at the client device (e.g., a result of the user interaction) can be received from the client device at the server.

It is understood that any specific order or hierarchy of steps in the processes disclosed is an illustration of exemplary approaches. Based upon design preferences, it is understood that the specific order or hierarchy of steps in the processes may be rearranged, or that all illustrated steps be performed. Some of the steps may be performed simultaneously. For example, in certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Furthermore, the exemplary methodologies described herein may be implemented by a system including processing circuitry or a computer program product including instructions which, when executed by at least one processor, causes the processor to perform any of the methodology described herein.

As described above, embodiments of the present disclosure are particularly useful for ML-assisted completion design. Advantages of the present disclosure relative to conventional completion design techniques include, but are not limited to, improved planning of wells, optimization of completions, and production forecasting through the use of well models that better represent the reservoir conditions in the location of the well and automated work processes that allow the economic optimization of the completions. Such improvements may be realized as a result of using well models that are based on (or calibrated with) static and dynamic reservoir properties along with parameters predicted by different ML models as described herein using production and design data from existing wells.

In some embodiments of the present disclosure, a computer-implemented method for completion design includes: acquiring, by a computing device from a data store, wellsite data for one or more existing production wells in a hydrocarbon producing field; transforming, by the computing device, the wellsite data into one or more model data sets for predictive modeling; training a first machine learning (ML) model to predict well logs for the one or more existing production wells, based on the one or more model data sets; generating a first well model to estimate production for the one or more existing production wells, based on the well logs predicted using the trained first ML model; tuning parameters of the first well model, based on a comparison between the estimated production and an actual production of the one or more existing production wells; training a second ML model to predict parameters of a second well model for a new production well in the hydrocarbon producing field, based on the tuned parameters of the first well model, the parameters of the second well model including completion design parameters for the new production well; forecasting production of the new production well over a period of time, based on the predicted parameters of using the trained second ML well model, the predicted parameters of the second well model including completion design parameters for the new production well; estimating completion costs for the new production well, based on the completion design parameters and the forecasted production over the period of time; and adjusting one or more of the completion design parameters for the new production well, based on the estimated completion costs and the forecasted production.

In other embodiments of the present disclosure, a computer-readable storage medium with instructions stored therein, where the instructions, when executed by a computer, cause the computer to perform a plurality of functions, including functions to: acquire wellsite data for one or more existing production wells in a hydrocarbon producing field; transform the wellsite data into one or more model data sets for predictive modeling; train a first machine learning (ML) model to predict well logs for the one or more existing production wells, based on the one or more model data sets; generate a first well model to estimate production for the one or more existing production wells, based on the well logs predicted using the trained first ML model; tune parameters of the first well model, based on a comparison between the estimated production and an actual production of the one or more existing production wells; train a second ML model to predict parameters of a second well model for a new production well in the hydrocarbon producing field, based on the tuned parameters of the first well model; forecast production of the new production well over a period of time, based on the predicted parameters of the second well model, the predicted parameters of the second well model including completion design parameters for the new production well; estimate completion costs for the new production well, based on the completion design parameters and the forecasted production over the period of time; and adjust one or more of the completion design parameters for the new production well, based on the estimated completion costs and the forecasted production.

Embodiments of the foregoing method and computer-readable storage medium may include any one of the following functions, operations, or elements, alone or in combination with each other: the tuning of the parameters of the first well model includes comparing the estimated production of the one or more existing production wells with the actual production of the one or more existing production wells, determining whether there is an acceptable match between the estimated production and the actual production of the one or more existing wells, based on the comparison and an error tolerance, and adjusting one or more of the parameters of the first well model to reduce a difference between the estimated production and the actual production of the one or more existing production wells when it is determined that there is no acceptable match between the estimated production and the actual production; the wellsite data acquired for the one or more existing production wells includes static and dynamic data; the wellsite data includes production data, well completion data, and geologic data associated with the one or more existing production wells; the parameters of the first well model include a porosity, a permeability, and a fluid saturation of an underlying reservoir formation associated with the one or more existing production wells; each of the first and second ML models is a neural network; each of the first and second well models is a near wellbore model; and the adjusting of the one or more completion design parameters for the new production well is performed as part of an automated workflow for monitoring production operations of the one or more existing production wells to acquire production data and automatically history matching the one or more completion design parameters for the new production well based on the acquired production data along with the estimated completion costs and the forecasted production for the new production well.

In further embodiments of the present disclosure, a system includes a processor and a memory coupled to the processor that has instructions stored therein, which, when executed by the processor, cause the processor to perform functions, including functions to: acquire wellsite data for one or more existing production wells in a hydrocarbon producing field; transform the wellsite data into one or more model data sets for predictive modeling; train a first machine learning (ML) model to predict well logs for the one or more existing production wells, based on the one or more model data sets; generate a first well model to estimate production for the one or more existing production wells, based on the well logs predicted using the trained first ML model; tune parameters of the first well model, based on a comparison between the estimated production and an actual production of the one or more existing production wells; train a second ML model to predict parameters of a second well model for a new production well in the hydrocarbon producing field, based on the tuned parameters of the first well model; forecast production of the new production well over a period of time, based on the predicted parameters of the second well model, the predicted parameters of the second well model including completion design parameters for the new production well; estimate completion costs for the new production well, based on the completion design parameters and the forecasted production over the period of time; and adjust one or more of the completion design parameters for the new production well, based on the estimated completion costs and the forecasted production.

Embodiments of the foregoing system may include any one of the following functions, operations, or elements, alone or in combination with each other: the tuning of the parameters of the first well model includes comparing the estimated production of the one or more existing production wells with the actual production of the one or more existing production wells, determining whether there is an acceptable match between the estimated production and the actual production of the one or more existing wells, based on the comparison and an error tolerance, and adjusting one or more of the parameters of the first well model to reduce a difference between the estimated production and the actual production of the one or more existing production wells when it is determined that there is no acceptable match between the estimated production and the actual production; the wellsite data acquired for the one or more existing production wells includes static and dynamic data; the wellsite data includes production data, well completion data, and geologic data associated with the one or more existing production wells; the parameters of the first well model include a porosity, a permeability, and a fluid saturation of an underlying reservoir formation associated with the one or more existing production wells; each of the first and second ML models is a neural network; each of the first and second well models is a near wellbore model; and the adjusting of the one or more completion design parameters for the new production well is performed as part of an automated workflow for monitoring production operations of the one or more existing production wells to acquire production data and automatically history matching the one or more completion design parameters for the new production well based on the acquired production data along with the estimated completion costs and the forecasted production for the new production well.

While specific details about the above embodiments have been described, the above hardware and software descriptions are intended merely as example embodiments and are not intended to limit the structure or implementation of the disclosed embodiments. For instance, although many other internal components of the system 900 are not shown, those of ordinary skill in the art will appreciate that such components and their interconnection are well known.

In addition, certain aspects of the disclosed embodiments, as outlined above, may be embodied in software that is executed using one or more processing units/components. Program aspects of the technology may be thought of as “products” or “articles of manufacture” typically in the form of executable code and/or associated data that is carried on or embodied in a type of machine readable medium. Tangible non-transitory “storage” type media include any or all of the memory or other storage for the computers, processors or the like, or associated modules thereof, such as various semiconductor memories, tape drives, disk drives, optical or magnetic disks, and the like, which may provide storage at any time for the software programming.

Additionally, the flowchart and block diagrams in the figures illustrate the architecture, functionality, and operation of possible implementations of systems, methods and computer program products according to various embodiments of the present disclosure. It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

The above specific example embodiments are not intended to limit the scope of the claims. The example embodiments may be modified by including, excluding, or combining one or more features or functions described in the disclosure.

As used herein, the singular forms “a”, “an” and “the” are intended to include the plural forms as well, unless the context clearly indicates otherwise. It will be further understood that the terms “comprise” and/or “comprising,” when used in this specification and/or the claims, specify the presence of stated features, integers, steps, operations, elements, and/or components, but do not preclude the presence or addition of one or more other features, integers, steps, operations, elements, components, and/or groups thereof. The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and explanation but is not intended to be exhaustive or limited to the embodiments in the form disclosed. Many modifications and variations will be apparent to those of ordinary skill in the art without departing from the scope and spirit of the disclosure. The illustrative embodiments described herein are provided to explain the principles of the disclosure and the practical application thereof, and to enable others of ordinary skill in the art to understand that the disclosed embodiments may be modified as desired for a particular implementation or use. The scope of the claims is intended to broadly cover the disclosed embodiments and any such modification.

What is claimed is:

1. A computer-implemented method of parameter matching for completion design, the method comprising:
acquiring, by a computing device, wellsite data for one or more existing production wells in a hydrocarbon producing field;
transforming, by the computing device, the wellsite data into one or more model data sets for predictive modeling;
training a first machine learning (ML) model to predict well logs for the one or more existing production wells, based on the one or more model data sets;
generating a first well model to estimate production for the one or more existing production wells, based on the well logs predicted using the trained first ML model;
tuning parameters of the first well model, based on a comparison between the estimated production and an actual production of the one or more existing production wells;
training a second ML model to predict parameters of a second well model for a new production well in the hydrocarbon producing field, based on the tuned parameters of the first well model;
forecasting production of the new production well over a period of time, based on the predicted parameters of the second well model, the predicted parameters of the second well model including completion design parameters for the new production well;
estimating completion costs for the new production well, based on the completion design parameters and the forecasted production over the period of time; and
adjusting one or more of the completion design parameters for the new production well, based on the estimated completion costs and the forecasted production.

2. The method of claim 1, wherein the tuning of the parameters of the first well model comprises:
comparing the estimated production of the one or more existing production wells with the actual production of the one or more existing production wells;
determining whether there is an acceptable match between the estimated production and the actual production of the one or more existing wells, based on the comparison and an error tolerance; and
when it is determined that there is no acceptable match between the estimated production and the actual production, adjusting one or more of the parameters of the first well model to reduce a difference between the estimated production and the actual production of the one or more existing production wells.

3. The method of claim 1, wherein the wellsite data acquired for the one or more existing production wells includes static and dynamic data.

4. The method of claim 1, wherein the wellsite data includes production data, well completion data, and geologic data associated with the one or more existing production wells.

5. The method of claim 1, wherein the parameters of the first well model include a porosity, a permeability, and a fluid saturation of an underlying reservoir formation associated with the one or more existing production wells.

6. The method of claim 1, wherein each of the first and second ML models is a neural network.

7. The method of claim 1, wherein each of the first and second well models is a near wellbore model.

8. The method of claim 7, wherein the adjusting of the one or more completion design parameters for the new production well is performed as part of an automated workflow for monitoring production operations of the one or more existing production wells to acquire production data and automatically history matching the one or more completion design parameters for the new production well based on the acquired production data along with the estimated completion costs and the forecasted production for the new production well.

9. A system comprising:
a processor; and
a memory coupled to the processor having instructions stored therein, which, when executed by the processor, cause the processor to perform a plurality of functions, including functions to:
acquire wellsite data for one or more existing production wells in a hydrocarbon producing field;
transform the wellsite data into one or more model data sets for predictive modeling;
train a first machine learning (ML) model to predict well logs for the one or more existing production wells, based on the one or more model data sets;
generate a first well model to estimate production for the one or more existing production wells, based on the well logs predicted using the trained first ML model;
tune parameters of the first well model, based on a comparison between the estimated production and an actual production of the one or more existing production wells;
train a second ML model to predict parameters of a second well model for a new production well in the hydrocarbon producing field, based on the tuned parameters of the first well model;
forecast production of the new production well over a period of time, based on the predicted parameters of the second well model, the predicted parameters of the second well model including completion design parameters for the new production well;
estimate completion costs for the new production well, based on the completion design parameters and the forecasted production over the period of time; and
adjust one or more of the completion design parameters for the new production well, based on the estimated completion costs and the forecasted production.

10. The system of claim 9, wherein the functions performed by the processor further include functions to:
compare the estimated production of the one or more existing production wells with the actual production of the one or more existing production wells;
determine whether there is an acceptable match between the estimated production and the actual production of the one or more existing wells, based on the comparison and an error tolerance; and
adjust one or more of the parameters of the first well model to reduce a difference between the estimated production and the actual production of the one or more existing production wells, when it is determined that there is no acceptable match between the estimated production and the actual production.

11. The system of claim 9, wherein the wellsite data acquired for the one or more existing production wells includes static and dynamic data.

12. The system of claim 9, wherein the wellsite data includes production data, well completion data, and geologic data associated with the one or more existing production wells.

13. The system of claim 9, wherein the parameters of the first well model include a porosity, a permeability, and a fluid saturation of an underlying reservoir formation associated with the one or more existing production wells.

14. The system of claim 9, wherein each of the first and second ML models is a neural network.

15. The system of claim 9, wherein each of the first and second well models is a near wellbore model.

16. The system of claim 15, wherein the one or more completion design parameters of the new production well are adjusted as part of an automated workflow for monitoring production operations of the one or more existing production wells to acquire production data and automatically history matching the one or more completion design parameters for the new production well based on the acquired production data along with the estimated completion costs and the forecasted production for the new production well.

17. A computer-readable storage medium having instructions stored therein, which, when executed by a computer, cause the computer to perform a plurality of functions, including functions to:
acquire wellsite data for one or more existing production wells in a hydrocarbon producing field;
transform the wellsite data into one or more model data sets for predictive modeling;
train a first machine learning (ML) model to predict well logs for the one or more existing production wells, based on the one or more model data sets;
generate a first well model to estimate production for the one or more existing production wells, based on the well logs predicted using the trained first ML model;
tune parameters of the first well model, based on a comparison between the estimated production and an actual production of the one or more existing production wells;
train a second ML model to predict parameters of a second well model for a new production well in the hydrocarbon producing field, based on the tuned parameters of the first well model;
forecast production of the new production well over a period of time, based on the predicted parameters of the second well model, the predicted parameters of the second well model including completion design parameters for the new production well;
estimate completion costs for the new production well, based on the completion design parameters and the forecasted production over the period of time; and
adjust one or more of the completion design parameters for the new production well, based on the estimated completion costs and the forecasted production.

18. The computer-readable storage medium of claim 17, wherein the functions performed by the computer further include functions to:
compare the estimated production of the one or more existing production wells with the actual production of the one or more existing production wells;
determine whether there is an acceptable match between the estimated production and the actual production of the one or more existing wells, based on the comparison and an error tolerance; and
adjust one or more of the parameters of the first well model to reduce a difference between the estimated production and the actual production of the one or more existing production wells, when it is determined that there is no acceptable match between the estimated production and the actual production.

19. The computer-readable storage medium of claim 17, wherein the wellsite data acquired for the one or more existing production wells includes static and dynamic data, and the parameters of the first well model include a porosity, a permeability, and a fluid saturation of an underlying reservoir formation associated with the one or more existing production wells.

20. The computer-readable storage medium of claim 17, wherein each of the first and second ML models is a neural network, each of the first and second well models is a near wellbore model, and the one or more completion design parameters of the new production well are adjusted as part of an automated workflow for monitoring production operations of the one or more existing production wells in the hydrocarbon producing field to acquire production data and automatically history matching the one or more completion design parameters for the new production well based on the acquired production data along with the estimated completion costs and the forecasted production for the new production well.
